(19) United States
(12) Patent Application Publication
(10) Pub. No.: US 2026/0023101 A1
(43) Pub. Date: Jan. 22, 2026

(54) CURRENT SENSOR AND CURRENT SENSOR MODULE

(71) Applicant: Asahi Kasei Microdevices Corporation, Tokyo (JP)

(72) Inventor: Kenji SUZUKI, Tokyo (JP)

(21) Appl. No.: 19/264,829

(22) Filed: Jul. 9, 2025

(30) Foreign Application Priority Data
Jul. 16, 2024 (JP) 2024-113399
Jun. 5, 2025 (JP) 2025-094348

(51) Int. Cl. G01R 15/20; G01R 19/00

(52) U.S. Cl. CPC G01R 15/207; G01R 15/202; G01R 19/0092

(57) ABSTRACT

A sealing section seals a part of the first current conductor, the first magnetoelectric conversion element, a part of the second current conductor, the second magnetoelectric conversion element, the signal processing IC, and a part of the signal conductor. At least one of the first magnetoelectric conversion element or the second magnetoelectric conversion element may be arranged on a circuit surface of the signal processing IC. A part of the first current conductor may be exposed from a first surface of the sealing section. A part of the second current conductor may be exposed from a second surface which is opposite to the first surface of the sealing section in a first direction. A part of the signal conductor may be exposed from a third surface which is different from the first surface and the second surface of the sealing section.

The contents of the following patent application(s) are incorporated herein by reference:
NO. 2024-113399 filed in JP on Jul. 16, 2024
NO. 2025-094348 filed in JP on Jun. 5, 2025.

### BACKGROUND

### 1. Technical Field

The present invention relates to a current sensor and a current sensor module.

### 2. Related Art

Patent Document 1 discloses a current sensor which is able to measure a measuring target current for two channels.

### RELATED ART DOCUMENTS

### Patent Document

Patent Document 1: International Publication No. WO 2015/033541

### BRIEF DESCRIPTION OF THE DRAWINGS

FIG. 1A is a schematic plan view of a current sensor and a substrate according to a first embodiment as seen from above a ceiling surface side (a positive direction of a Z axis).

FIG. 1B is a cross-sectional view taken along a line A-A of the current sensor and the substrate shown in FIG. 1A.

FIG. 1C is a side view of the current sensor and the substrate as seen from a positive direction of a y axis shown in FIG. 1A.

FIG. 2 is a diagram for describing a positional relationship between a magnetoelectric conversion element and a current conductor in the first embodiment.

FIG. 3 is a diagram for describing a positional relationship between the magnetoelectric conversion element and the current conductor according to a modified example of the first embodiment.

FIG. 4 is a diagram for describing a near region of the current conductor in which the magnetoelectric conversion element is arranged.

FIG. 5 is a cross-sectional view taken along the line A-A of the current sensor in the first embodiment in a case of an insertion mounting type.

FIG. 6A is a schematic plan view of the current sensor and the substrate according to a second embodiment as seen from above a ceiling surface side (the positive direction of the Z axis).

FIG. 6B is a cross-sectional view taken along a line A-A of the current sensor and the substrate shown in FIG. 6A.

FIG. 6C is a side view of the current sensor and the substrate as seen from the positive direction of the y axis shown in FIG. 6A.

FIG. 7A is a diagram for describing another example of the positional relationship between the magnetoelectric conversion element and the current conductor.

FIG. 7B is a diagram for describing another example of the positional relationship between the magnetoelectric conversion element and the current conductor.

FIG. 8 is a cross-sectional view taken along the line A-A of the current sensor in the second embodiment in the case of an insertion mounting type.

FIG. 9A is a plan view of a signal processing IC, the magnetoelectric conversion element, and the current conductor, in an original case.

FIG. 9B is a plan view of the signal processing IC, the magnetoelectric conversion element, and the current conductor, in a case 1.

FIG. 9C is a plan view of the signal processing IC, the magnetoelectric conversion element, and the current conductor, in a case 2.

FIG. 9D is a plan view of the signal processing IC, the magnetoelectric conversion element, and the current conductor, in a case 3.

FIG. 10 is a table showing heat generation reduction effectiveness in the original case, the case 1, the case 2, and the case 3.

FIG. 11 is a diagram showing a degree of the heat generation reduction effectiveness in accordance with ratios of a width of the signal processing IC to a width of the current conductor in the case 1, the case 2, and the case 3.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention.

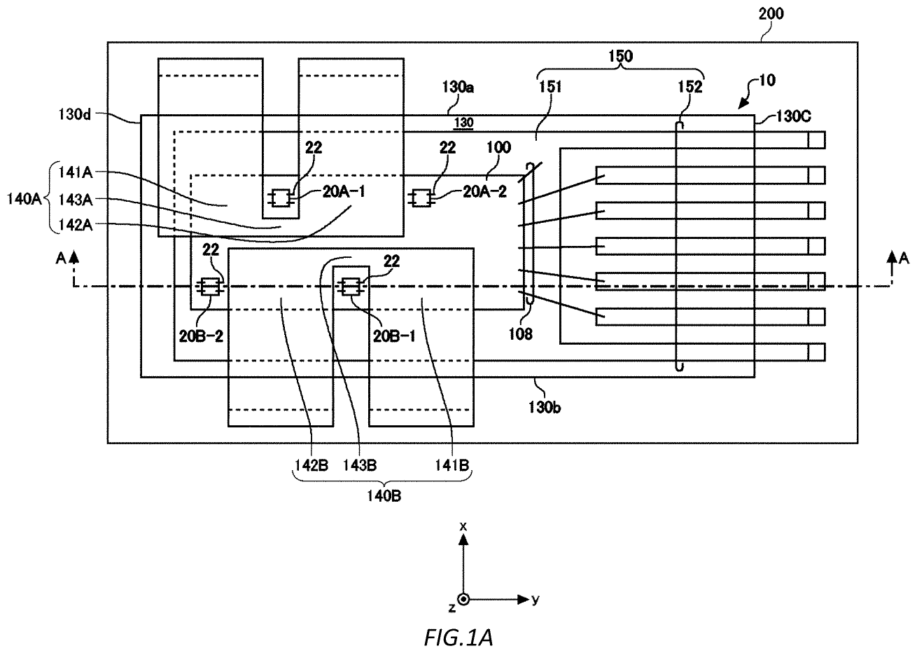

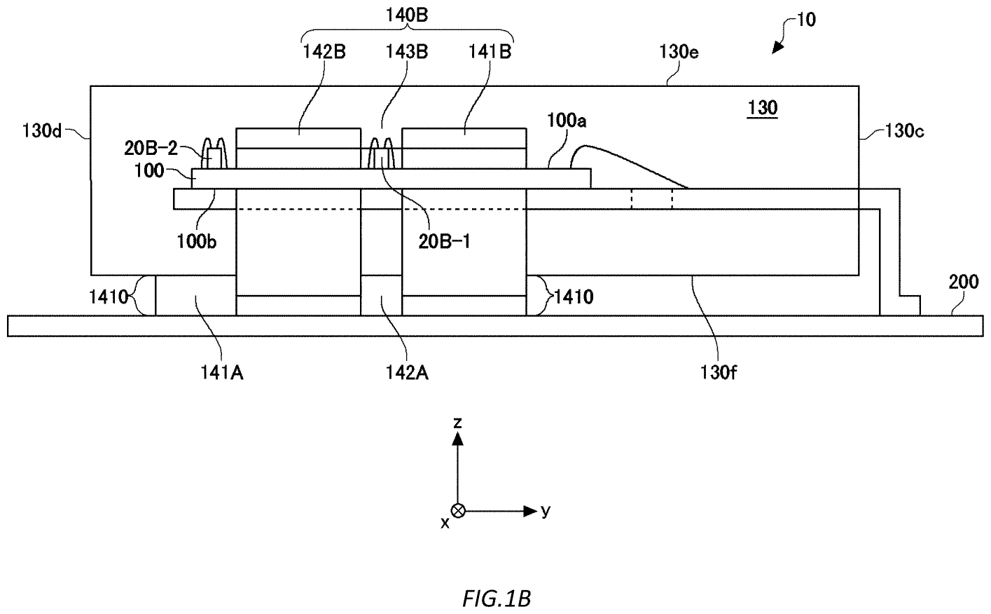

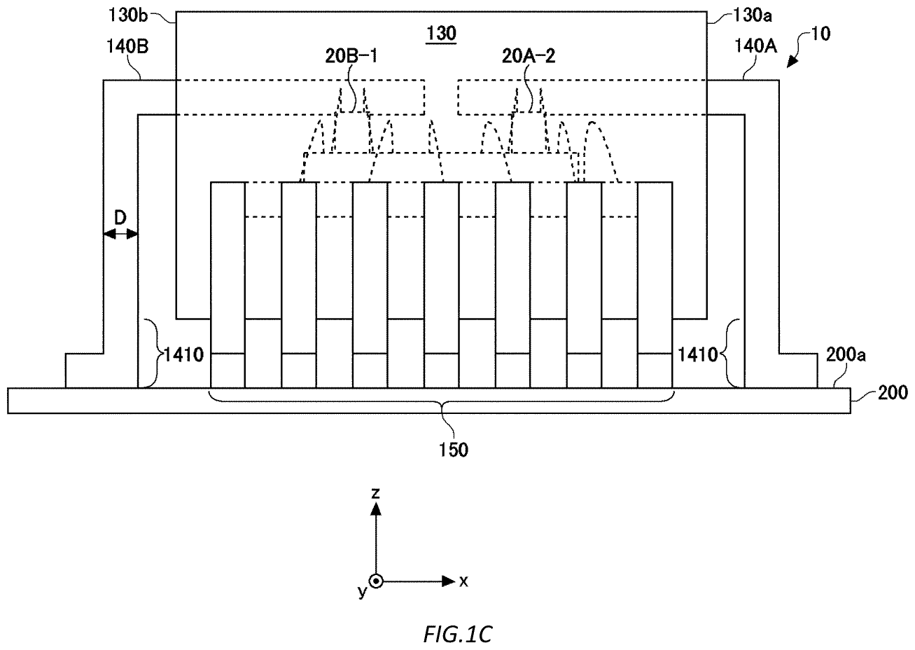

FIG. 1A is a schematic plan view of a current sensor 10 and a substrate 200 according to a first embodiment as seen from above a ceiling surface side (a positive direction of a z axis). FIG. 1B is a cross-sectional view taken along a line A-A of the current sensor 10 and the substrate 200 shown in FIG. 1A. FIG. 1C is a side view of the current sensor 10 and the substrate 200 as seen from a positive direction of a y axis shown in FIG. 1A. In FIG. 1A, for the coordinates, a direction that is parallel to a plane of paper and that is from below to above is defined as an x axis direction; a direction that is parallel to the plane of paper and that is from a left to a right is defined as a y axis direction; and a direction that is perpendicular to the plane of paper and that is from a back to a front is defined as a z axis direction. Any one axis among an x axis, the y axis, and the z axis is orthogonal to another axis.

The current sensor 10 includes: a signal processing IC 100; magnetoelectric conversion elements 20A-1, 20A-2, 20B-1, 20B-2; current conductors 140A, 140B on a primary side; a signal conductor 150 on a secondary side; and a sealing section 130. The current sensor 10 includes two current conductors 140A, 140B to measure measuring target currents for two channels. The magnetoelectric conversion elements 20A-1, 20A-2, 20B-1, 20B-2 may be collectively referred to as a magnetoelectric conversion element 20. The magnetoelectric conversion element 20A-1 is an example of a first magnetoelectric conversion element. The magnetoelectric conversion element 20A-2 is an example of a third magnetoelectric conversion element. The magnetoelectric conversion element 20B-1 is an example of a second magnetoelectric conversion element. The magnetoelectric conversion element 20B-2 is an example of a fourth magnetoelectric conversion element. The current conductor 140A is an example of a first current conductor. The current conductor 140B is an example of a second current conductor.

The sealing section 130 seals, with a resin material, the magnetoelectric conversion element 20, a part of the current conductor 140A, a part of the current conductor 140B, the signal processing IC 100, and the signal conductor 150. The resin material may be, for example, an epoxy-based thermosetting resin to which silica is added, or a thermoplastic resin such as a liquid crystal polymer. The sealing section 130 may be formed by compression molding, transfer molding, or the like using a mold.

The current conductor 140A and the current conductor 140B are conductors through which the measuring target currents that are measuring targets different from each other, flow respectively. The current conductor 140A and the current conductor 140B are electrically connected to electric wires of any two phases (for example, a U phase and a V phase), among three-phase electric wires of a three-phase AC circuit, such as a three-phase motor, through which the measuring target current of the measuring target flows. In a plan view, the current conductor 140A may have the same shape as that of the current conductor 140B. The current conductor 140A and the current conductor 140B may be constituted by one lead frame.

In the plan view, the current conductor 140A includes: a conductor portion 141A and a conductor portion 142A which extend in the x axis direction and are spaced apart from each other in the y axis direction; and a conductor portion 143A which extends in the y axis direction and links the conductor portion 141A to the conductor portion 142A. In the plan view, the conductor portion 141A and the conductor portion 142A, and the conductor portion 143A may form a U shape. One end of the conductor portion 141A and one end of conductor portion 142A are exposed from a surface 130a of the sealing section 130. The conductor portion 143A links another end of the conductor portion 141A and another end of the conductor portion 142A. The conductor portion 141A is an example of a first conductor portion, the conductor portion 142A is an example of a second conductor portion, and a conductor portion 143A is an example of a third conductor portion.

In the plan view, the current conductor 140B includes: a conductor portion 141B and a conductor portion 142B which extend in the x axis direction and are spaced apart from each other in the y axis direction; and a conductor portion 143B which extends in the y axis direction and links the conductor portion 141B to the conductor portion 142B. In the plan view, the conductor portion 141B and the conductor portion 142B, and the conductor portion 143B may form a U shape. One end of the conductor portion 141B and one end of conductor portion 142B are exposed from a surface 130b which is opposite to the surface 130a of the sealing section 130. The conductor portion 143B links another end of the conductor portion 141B and another end of the conductor portion 142B. The conductor portion 141B is an example of a fourth conductor portion, the conductor portion 142B is an example of a fifth conductor portion, and a conductor portion 143B is an example of a sixth conductor portion.

The signal conductor 150 may be constituted by another lead frame different from the lead frame that constitutes the current conductor 140A and the current conductor 140B. That is, the current conductor 140A is at the same height as that of the current conductor 140B within the sealing section 130, and the signal conductor 150 may be at a height different from those of the current conductor 140A and the current conductor 140B. The signal conductor 150 includes a support section 151 and a terminal section 152. The terminal section 152 is electrically connected to the signal processing IC 100 via a wire 108. A signal that is output from the signal processing IC 100 is output to an outside via the signal conductor 150. Some terminal section 152 is exposed from a surface 130c which is different from the surface 130a and the surface 130b which are opposite to each other in the x axis direction of the sealing section 130. The surface 130c is opposite to a surface 130d in the y axis direction. The terminal section 152 is exposed only from the surface 130c and is not exposed from the surface 130d. From the surface 130d, no other signal conductor which transmits the signal that is output from the signal processing IC 100 is exposed.

The support section 151 is sealed within the sealing section 130, and supports the signal processing IC 100. The terminal section 152 has a plurality of terminals, and some of the plurality of terminals are constituted to be physically integrated with the support section 151. At least a part of each of the plurality of terminals is exposed from the surface 130c of the sealing section 130.

The current conductor 140A, the current conductor 140B, and the signal conductor 150 may be constituted by conductive materials of which a main component is copper. The support section 151 may be constituted in combination of a metal plate which is a body separate from the terminal section 152, a plate constituted by a semiconductor, or an insulating material such as die attach film.

The magnetoelectric conversion element 20 may have a substrate constituted by silicon or a compound semiconductor, and a magnetoelectric conversion portion provided on the substrate. The magnetoelectric conversion element 20 has a sensitivity axis in the z axis direction. A magnetic field in the z axis direction is detected, and thus in the first embodiment, for example, a Hall element which detects a longitudinal magnetic field in a thickness direction of the current conductor 140A or the current conductor 140B is suitable as the magnetoelectric conversion element 20.

The signal processing IC 100 is a large-scale integrated circuit (LSI). The signal processing IC 100 is a monolithic IC. More specifically, the signal processing IC 100 is a signal processing circuit constituted by a Si monolithic semiconductor formed on a Si substrate. The signal processing IC 100 has a circuit surface in which the magnetoelectric conversion element 20 is arranged. In the first embodiment, the circuit surface corresponds to a surface 100a which corresponds to a ceiling surface of a semiconductor package that constitutes the signal processing IC 100. The surface 100a is an example of the circuit surface of the signal processing IC 100. The signal processing circuit processes an output signal in accordance with an intensity of the magnetic field that is output from the magnetoelectric conversion element 20.

The signal processing circuit cancels noise components that are included in the output signal of the magnetoelectric conversion element 20A-1 and the output signal of the magnetoelectric conversion element 20A-2 and that are due to a common external magnetic field, based on a difference between the output signal of the magnetoelectric conversion element 20A-1 and the output signal of the magnetoelectric conversion element 20A-2; amplifies the output signal of the magnetoelectric conversion element 20A-1 and the output signal of the magnetoelectric conversion element 20A-2 in which the noise components are reduced; calculates a current value Ia of the measuring target current flowing through the current conductor 140A, based on the amplified output signal; and outputs an output signal indicating the current value Ia. The signal processing circuit may perform an offset adjustment after canceling the noise component due to a disturbance magnetic field. The signal processing circuit may perform a correction by a temperature characteristic, when calculating the current value Ia based on the amplified output signal. That is, the signal processing circuit may: cancel the noise components due to the external magnetic field that is commonly applied to the magnetoelectric conversion element 20A-1 and the magnetoelectric conversion element 20A-2; extract only an output component based on the current flowing through the current conductor 140A; and output the output signal after performing the offset adjustment, the amplification of the output signal, and the correction by the temperature characteristic.

In addition, the signal processing circuit cancels noise components that are included in the output signal of the magnetoelectric conversion element 20B-1 and the output signal of the magnetoelectric conversion element 20B-2 and that are due to a common external magnetic field, based on a difference between the output signal of the magnetoelectric conversion element 20B-1 and the output signal of the magnetoelectric conversion element 20B-2; amplifies the output signal of the magnetoelectric conversion element 20B-1 and the output signal of the magnetoelectric conversion element 20B-2 in which the noise components are reduced; calculates a current value Ib of the measuring target current flowing through the current conductor 140B, based on the amplified output signal; and outputs an output signal indicating the current value Ib. Similarly, the signal processing circuit may: cancel the noise components due to the external magnetic field that is commonly applied to the magnetoelectric conversion element 20B-1 and the magnetoelectric conversion element 20B-2; extract only an output component based on the current flowing through the current conductor 140B; and output the output signal after performing the offset adjustment, the amplification of the output signal, and the correction by the temperature characteristic.

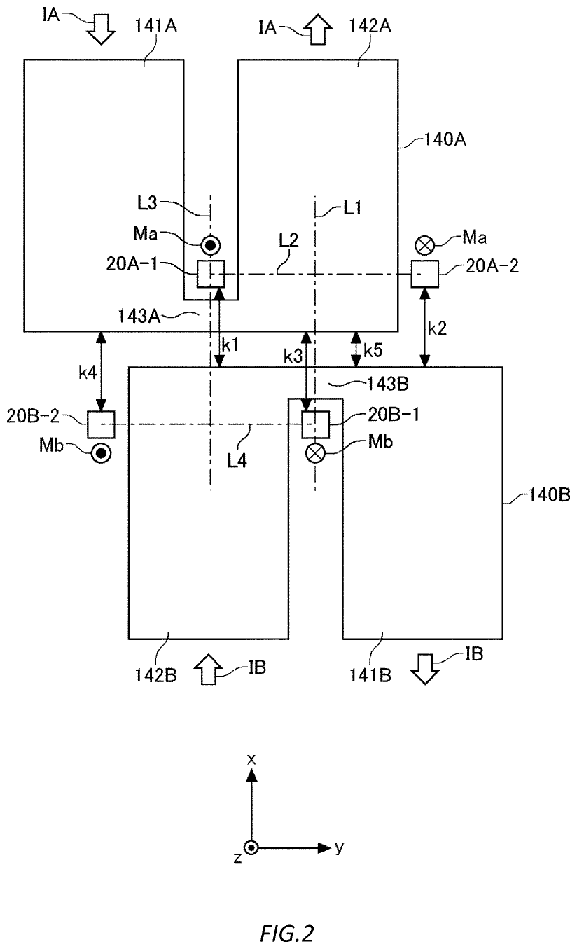

FIG. 2 is a diagram for describing a positional relationship between the magnetoelectric conversion element 20, and the current conductor 140A and the current conductor 140B in the first embodiment. In FIG. 2, an arrow IA indicates a direction of the measuring target current flowing through the current conductor 140A, and an arrow IB indicates a direction of the measuring target current flowing through the current conductor 140B. Marks indicated by a symbol Ma and a symbol Mb show directions of magnetic fluxes in regions where the marks are positioned.

In the plan view, the magnetoelectric conversion element 20A-1 is arranged in a region surrounded by the current conductor 140A. The magnetoelectric conversion element 20A-1 is arranged in a region surrounded by the conductor portion 141A, the conductor portion 143A, and the conductor portion 142A. In the plan view, the magnetoelectric conversion element 20A-2 is arranged to face the magnetoelectric conversion element 20A-1 across the conductor portion 142A. The magnetoelectric conversion element 20A-1 and the magnetoelectric conversion element 20A-2 are aligned along the y axis direction.

In the plan view, the magnetoelectric conversion element 20B-1 is arranged in a region surrounded by the current conductor 140B. The magnetoelectric conversion element 20B-1 is arranged in a region surrounded by the conductor portion 141B, the conductor portion 143B, and the conductor portion 142B. In the plan view, the magnetoelectric conversion element 20B-2 is arranged to face the magnetoelectric conversion element 20B-1 across the conductor portion 142B. The magnetoelectric conversion element 20B-1 and the magnetoelectric conversion element 20B-2 are aligned along the y axis direction.

In the plan view, a shape constituted by the conductor portion 141A, the conductor portion 142A, and the conductor portion 143A may be line-symmetrical with a symmetrical axis of a perpendicular bisector L3 of a line segment L4 connecting the magnetoelectric conversion element 20B-1 and the magnetoelectric conversion element 20B-2. In the plan view, a shape constituted by the conductor portion 141B, the conductor portion 142B, and the conductor portion 143B may be line-symmetrical with a symmetrical axis of a perpendicular bisector L1 of a line segment L2 connecting the magnetoelectric conversion element 20A-1 and the magnetoelectric conversion element 20A-2.

In the plan view, the magnetoelectric conversion element 20A-1 is positioned on an extension line along which the conductor portion 142B extends. In the plan view, the magnetoelectric conversion element 20A-2 is positioned on an extension line along which the conductor portion 141B extends. In the plan view, the magnetoelectric conversion element 20B-1 is positioned on an extension line along which the conductor portion 142A extends. In the plan view, the magnetoelectric conversion element 20B-2 is positioned on an extension line along which the conductor portion 141A extends. Further, in the plan view, the magnetoelectric conversion element 20A-1 is positioned on the perpendicular bisector L3 of the line segment L4 connecting the magnetoelectric conversion element 20B-1 and the magnetoelectric conversion element 20B-2. In the plan view, the magnetoelectric conversion element 20B-1 is positioned on the perpendicular bisector L1 of the line segment L2 connecting the magnetoelectric conversion element 20A-1 and the magnetoelectric conversion element 20A-2.

The conductor portion 143B is a current path extending in a direction along the line segment L2 connecting the magnetoelectric conversion element 20A-1 and the magnetoelectric conversion element 20A-2. In the plan view, a distance k1 between the magnetoelectric conversion element 20A-1 and the conductor portion 143B, is equal to a distance k2 between the magnetoelectric conversion element 20A-2 and the conductor portion 143B. Therefore, by the measuring target current flowing through the current conductor 140B, a magnetic field that is generated at the position of the magnetoelectric conversion element 20A-1 becomes equal to a magnetic field that is generated at the position of the magnetoelectric conversion element 20A-2. As described above, the signal processing circuit calculates the difference between the output signal of the magnetoelectric conversion element 20A-1 and the output signal of the magnetoelectric conversion element 20A-2. Therefore, by calculating the difference between the output signal of the magnetoelectric conversion element 20A-1 and the output signal of the magnetoelectric conversion element 20A-2, the signal processing circuit can cancel an influence of the magnetic field that is generated by the measuring target current flowing through the current conductor 140B. This makes it possible to suppress the influence of the magnetic field that is generated by the measuring target current flowing through the current conductor 140B, on a measurement result of the measuring target current flowing through the current conductor 140A, based on output results of the output signal of the magnetoelectric conversion element 20A-1 and the output signal of the magnetoelectric conversion element 20A-2.

Similarly, the conductor portion 143A is a current path extending in a direction along the line segment L4 connecting the magnetoelectric conversion element 20B-1 and the magnetoelectric conversion element 20B-2. In the plan view, a distance k3 between the magnetoelectric conversion element 20B-1 and the conductor portion 143A, is equal to a distance k4 between the magnetoelectric conversion element 20B-2 and the conductor portion 143A. Therefore, by the measuring target current flowing through the current conductor 140A, a magnetic field that is generated at the position of the magnetoelectric conversion element 20B-1 becomes equal to a magnetic field that is generated at the position of the magnetoelectric conversion element 20B-2. Therefore, by calculating the difference between the output signal of the magnetoelectric conversion element 20B-1 and the output signal of the magnetoelectric conversion element 20B-2, the signal processing circuit can cancel an influence of the magnetic field that is generated by the measuring target current flowing through the current conductor 140A. This makes it possible to suppress the influence of the magnetic field that is generated by the measuring target current flowing through the current conductor 140A, on a measurement result of the measuring target current flowing through the current conductor 140B, based on output results of the output signal of the magnetoelectric conversion element 20B-1 and the output signal of the magnetoelectric conversion element 20B-2.

As described above, the magnetoelectric conversion element 20 is mounted on the surface 100a of the signal processing IC 100, thereby making it possible to electrically connect the magnetoelectric conversion element 20 to the signal processing IC 100 by a wire 22 which does not cross over the current conductors 140A, 140B. Therefore, a deformation of the wire 22 is less likely to occur, it is comparatively easy to optimize a shape of the wire 22, and it is possible to suppress a deterioration of electrical characteristic such as responsiveness of the current sensor 10. The wire 22 and the wire 108 may be formed of a conductive material of which a main component is Au, Ag, Cu, or Al.

In this way, the magnetoelectric conversion element 20 is mounted on the surface 100a of the signal processing IC 100, and thus is able to be connected to the signal processing IC 100 via the wire 22 which does not cross over the current conductors 140A, 140B. Therefore, in the plan view, it is possible to shorten a distance between the current conductor 140A and the current conductor 140B, while the conductor portion 143A and the conductor portion 143B are arranged to be spaced apart to face each other. For example, in the plan view, a distance k5 between parts at which the current conductor 140A and the current conductor 140B face each other, that is, between the conductor portion 143A and the conductor portion 143B, may be 2 mm or less and 0.1 mm or more. Therefore, it is possible to reduce a width of the sealing section 130 in the x axis direction, and it is possible to reduce a size of the current sensor 10 which is able to measure the measuring target current for two channels. A resin material that constitutes the sealing section 130 fills between the conductor portion 143A and the conductor portion 143B. Therefore, it is also possible to ensure insulation between the conductor portion 143A and the conductor portion 143B. In addition, the wire 22 does not need to cross over the current conductor 140A and the current conductor 140B, and it is possible to shorten a wire length, and thus an influence of noise disturbance is less likely to occur, and it is possible to minimize wiring capacity, which can improve a response speed of the current sensor 10.

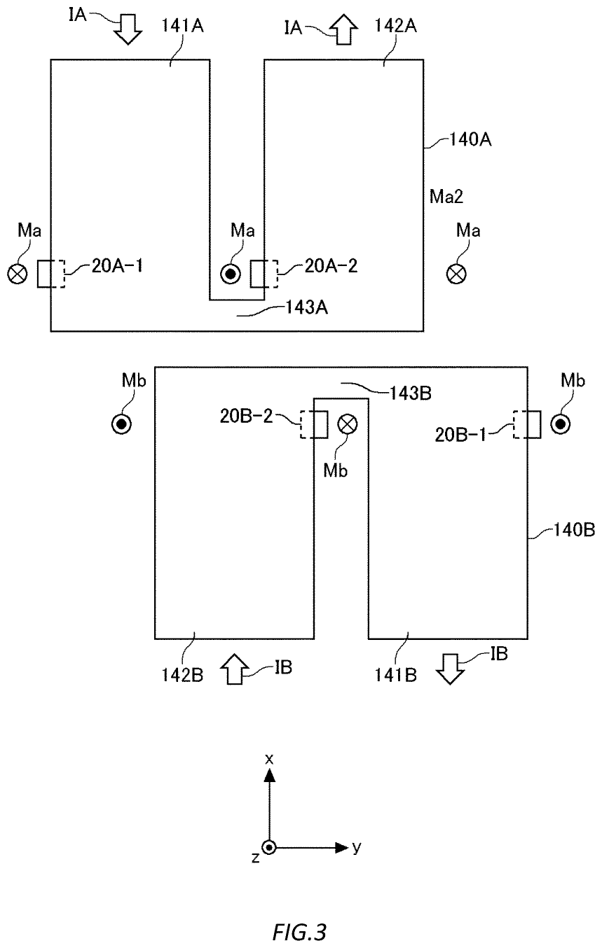

FIG. 3 is a diagram for describing a positional relationship between the magnetoelectric conversion element 20, and the current conductor 140A and the current conductor 140B according to a modified example of the first embodiment. The example shown in FIG. 2 has described the example in which in the plan view, the magnetoelectric conversion element 20, and the current conductor 140A and the current conductor 140B are arranged in positions that do not overlap with each other. However, as shown in FIG. 3, in the plan view, the magnetoelectric conversion element 20, and the current conductor 140A or the current conductor 140B may be arranged in positions partially overlapping with each other. In the plan view, the magnetoelectric conversion elements 20A-1 and 20A-2 may be arranged to face each other across a part of the conductor portion 141A. In the plan view, the magnetoelectric conversion elements 20B-1 and 20B-2 may be arranged to face each other across a part of the conductor portion 141B. In the plan view, half of a magnetosensitive surface of the magnetoelectric conversion element 20 may overlap with the current conductor 140A or the current conductor 140B.

As in the current sensor shown in FIG. 3, in the plan view, when the magnetoelectric conversion element 20 is arranged in a position partially overlapping with that of the current conductor 140A or the current conductor 140B, the magnetic field may be detected in the sensitivity axis of the magnetoelectric conversion element, not only in the z axis direction but also in either one of axial directions on an xy plane that is horizontal to the magnetosensitive surface. Accordingly, in the current sensor according to the modified example of the first embodiment shown in FIG. 3, the magnetoelectric conversion element 20 may be a Hall element using a Hall effect, or may be a magnetoresistance element using a magnetoresistive effect. The magnetoresistance element may be, for example, a semiconductor magnetoresistance element (SMR), an anomalous magnetoresistance element (AMR), a giant magnetoresistance element (GMR), or a tunnel magnetoresistance element (TMR).

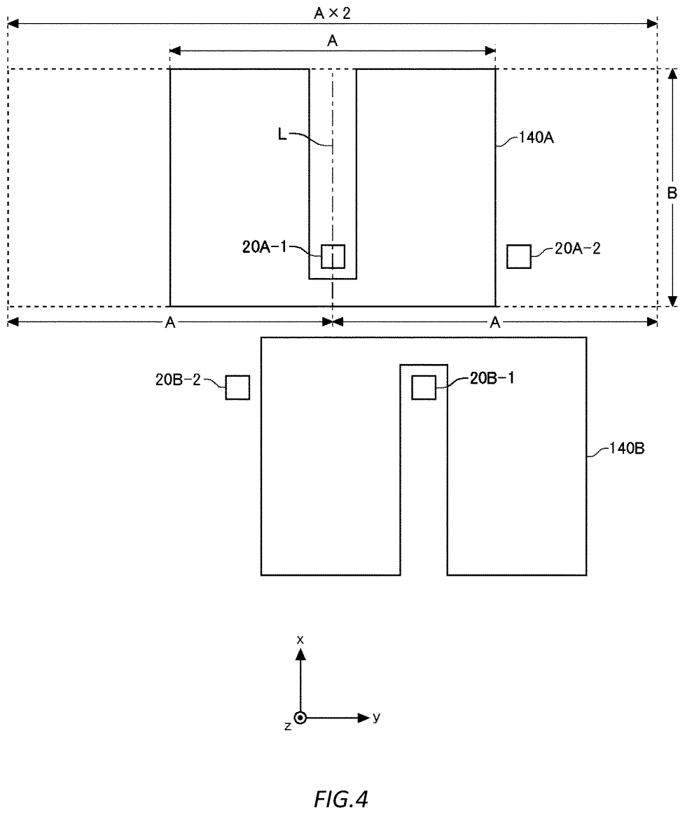

The positional relationship between the magnetoelectric conversion element 20, and the current conductor 140A and the current conductor 140B shown in FIG. 2 and FIG. 3 is merely an example. As long as the magnetoelectric conversion element 20 is arranged in a near region of the current conductor 140A or the current conductor 140B, it may be arranged in another position. Here, for example, as shown in FIG. 4, when a width of the current conductor 140A in the y axis direction is set as A and a width in the x axis direction is set as B, the near region may be a region that is included in: a range that is twice the width A in the y axis direction and that is centered on a symmetrical axis L of the current conductor 140A; and a range of the width B in the x axis direction.

The current sensor 10 shown in FIG. 1A to FIG. 1C is of a front surface mounting type in which the current conductor 140A and the current conductor 140B are arranged on a mounting surface of the substrate 200. Here, in a case where a slit or the like is provided in the substrate 200 to increase a creepage distance on a substrate 200 side, it may be good for the sealing section 130 of the current sensor 10 to be spaced apart from the substrate 200 so as not to undermine the effectiveness in the case. In other words, in order to prevent dielectric breakdown via a front surface of the current sensor 10, it may be good for the sealing section 130 to be spaced apart from the substrate 200. Therefore, parts of the conductor portion 141A and the conductor portion 142A that are respectively exposed from the surface 130a of the sealing section 130, and parts of the conductor portion 141B and the conductor portion 142B that are respectively exposed from the surface 100b of the sealing section 130, have extension portions 1410 which extend further in the z axis direction from a surface 130f of the sealing section 130 which faces a surface 100b on an opposite side of the circuit surface of the signal processing IC 100. By the extension portion 1410 being fixed to a mounting surface 200a of the substrate 200, the sealing section 130 is positioned above the mounting surface 200a. This makes it possible for a space to be provided between the sealing section 130 and the substrate 200. A distance between the mounting surface 200a of the substrate 200, and the surface 130f of the sealing section 130 which faces the mounting surface, is preferably 1 mm or more.

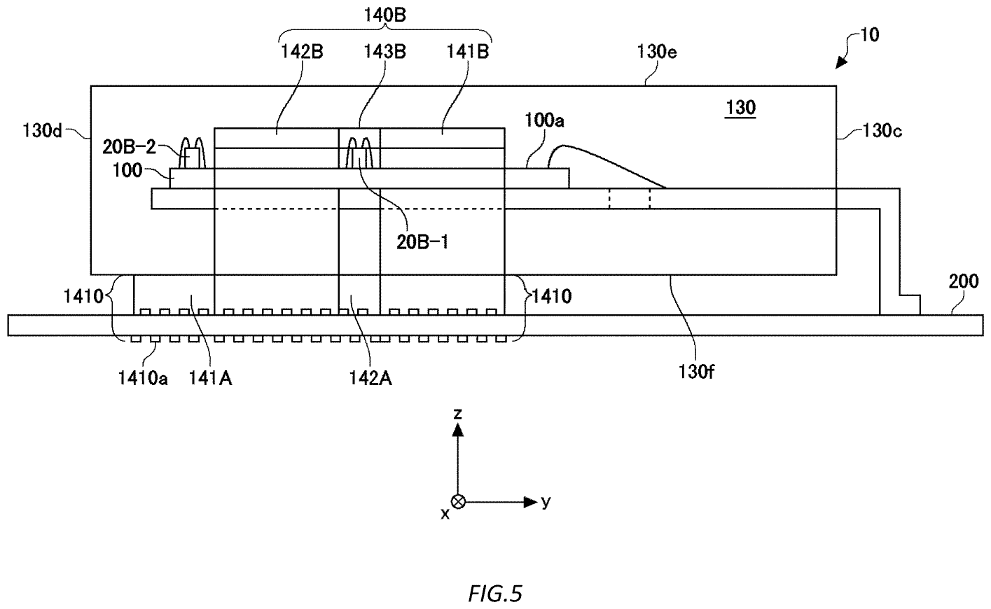

As described above, the current sensor 10 shown in FIG. 1A to FIG. 1C is an example of a front surface mounting type. However, the current sensor 10 may also be of an insertion mounting type in which the current conductor 140A and the current conductor 140B are inserted into the substrate 200. In the case of the insertion mounting type, an electrical connection to a copper foil of an inner layer of the substrate 200, is directly possible at a shortest distance from the current conductor 140A and the current conductor 140B, with a low resistance, and as a result, it becomes possible to suppress a heat generation of the substrate 200 to be low. In addition, when the extension portion 1410 is inserted into the substrate 200, it is good for a width of an edge of the extension portion 1410 to be narrower than a width of a part other than the edge of the extension portion 1410 to reliably ensure a space between the mounting surface 200a of the substrate 200 and the surface 130f of the sealing section 130. The narrow part of the edge of the extension portion 1410 is inserted into the substrate 200, and the part other than the edge of the extension portion 1410 comes into contact with the mounting surface 200a of the substrate 200. This makes it possible to reliably ensure the space between the mounting surface 200a of the substrate 200 and the surface 130f of the sealing section 130. For example, as shown in FIG. 5, the edge of the extension portion 1410 may include a plurality of tooth portions 1410a aligned in a comb shape. In this manner, it becomes possible to insert the tooth portions 1410a into a plurality of circular holes formed in the substrate 200, and establish a direct conduction to the inner layer of the substrate 200; and thus it also becomes possible to easily perform hole processing of the substrate 200, and it is possible to suppress the heat generation of the substrate 200 to be lower. For the hole processing of the substrate 200, for example, it is possible to use a drill or the like. A width of each of the plurality of tooth portions 1410a may be from 0.5 times to twice a thickness D of each of the conductor portion 141A, the conductor portion 142A, the conductor portion 141B, and the conductor portion 142B (shown in FIG. 1C). A cross-section of the plurality of tooth portions 1410a may be square.

It should be noted that in the substrate 200 shown in FIG. 1A to FIG. 1C, the slit may be provided on the front surface of the substrate 200 to obtain the creepage distance along the surface of the substrate 200. For example, in the plan view, the substrate 200 may have the slit extending in the x axis direction between the conductor portion 141A and the conductor portion 142A, and the terminal section 152. In the plan view, the substrate 200 may have the slit extending in the y axis direction between the conductor portion 141A and the conductor portion 142A, and the conductor portion 141B and the conductor portion 142B.

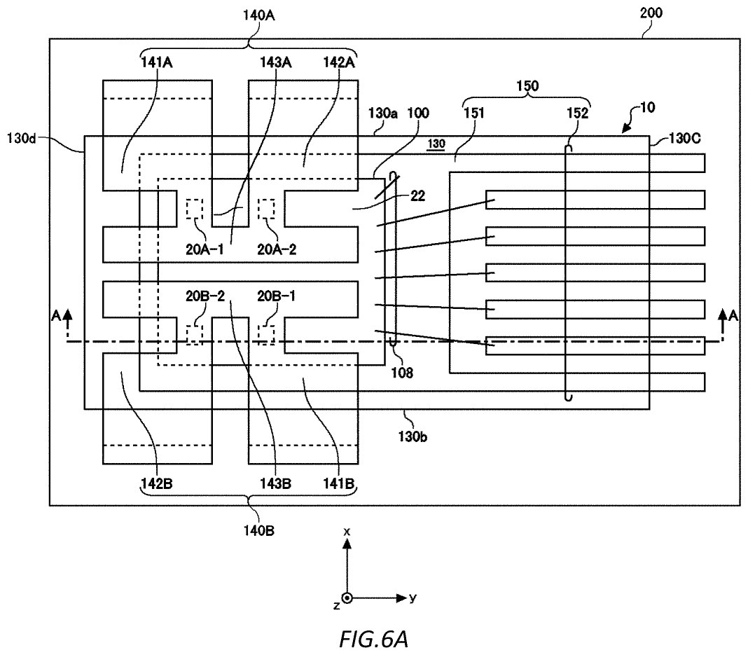

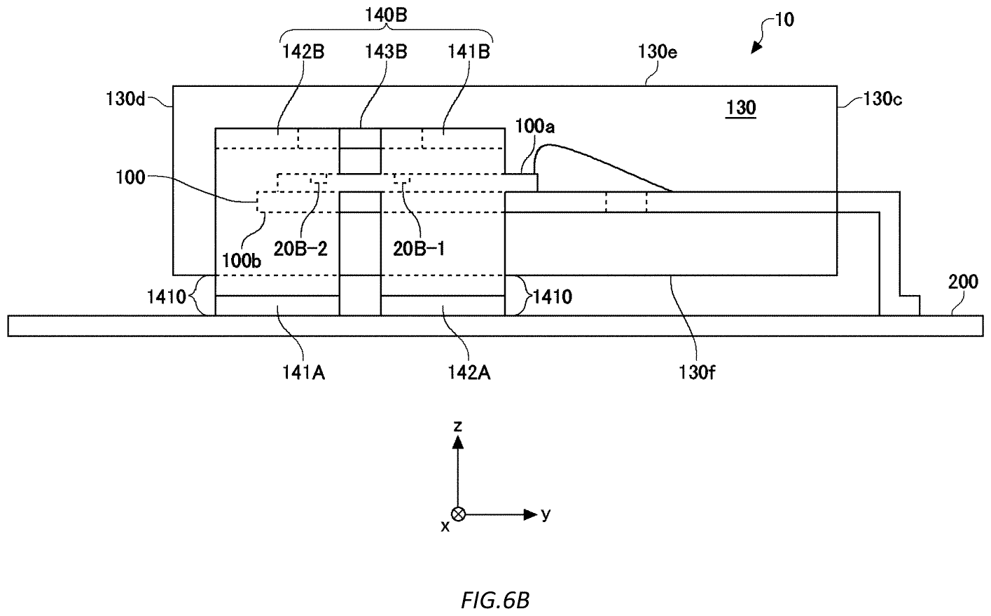

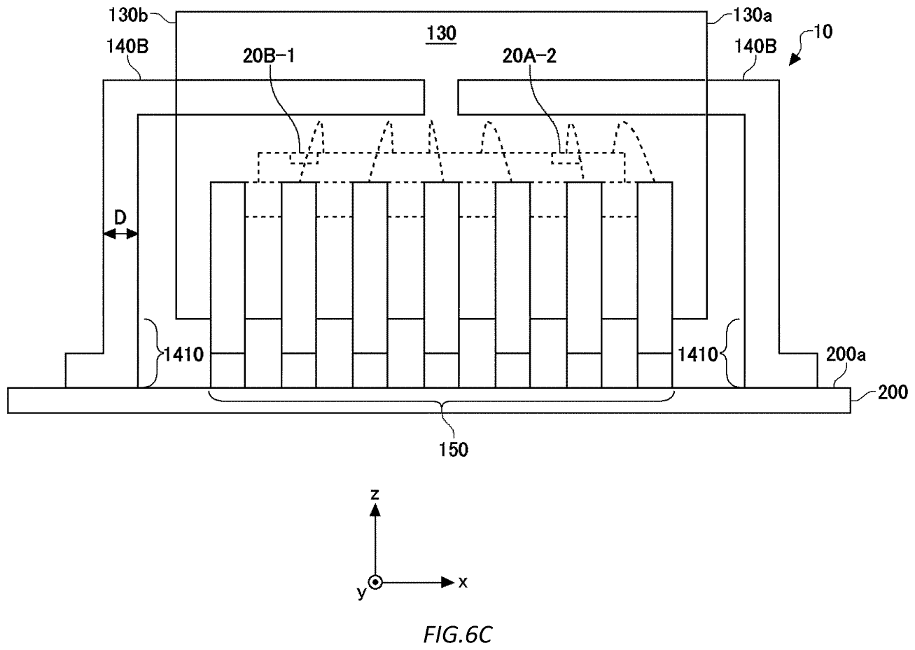

FIG. 6A is a schematic plan view of the current sensor 10 and the substrate 200 according to a second embodiment as seen from above a ceiling surface side (the positive direction of the z axis). FIG. 6B is a cross-sectional view taken along a line A-A of the current sensor 10 and the substrate 200 shown in FIG. 6A. FIG. 6C is a side view of the current sensor 10 and the substrate 200 as seen from the positive direction of the y axis shown in FIG. 6A. In FIG. 6A, for the coordinates, a direction that is parallel to a plane of paper and that is from below to above is defined as the x axis direction; a direction that is parallel to the plane of paper and that is from a left to a right is defined as the y axis direction; and a direction that is perpendicular to the plane of paper and that is from a back to a front is defined as the z axis direction. Any one axis among the x axis, the y axis, and the z axis is orthogonal to another axis.

The current sensor 10 according to the second embodiment is different from the current sensor 10 according to the first embodiment in that the magnetoelectric conversion element 20 is a magnetoresistance element. Further, in the plan view, the difference is that the magnetoelectric conversion element 20 overlaps with the current conductor 140A or the current conductor 140B. The magnetoelectric conversion element 20 detects the magnetic field in either one of the axial directions on the xy plane. That is, the magnetoelectric conversion element 20 has the sensitivity axis in a direction horizontal to the magnetosensitive surface. The magnetoelectric conversion element 20 may be a magnetoresistance element using the magnetoresistive effect. The magnetoresistance element may be, for example, a semiconductor magnetoresistance element (SMR), an anomalous magnetoresistance element (AMR), a giant magnetoresistance element (GMR), or a tunnel magnetoresistance element (TMR).

FIG. 6A shows the current sensor in which the magnetoelectric conversion element 20 is built in the signal processing IC 100; however, similar to FIG. 1A or the like, the magnetoelectric conversion element 20 may not be built in the signal processing IC 100, and may be installed on the circuit surface. That is, the current sensor 10 may have a monolithic structure in which the magnetoelectric conversion element 20 is built in the signal processing IC 100; and may have the magnetoelectric conversion element 20 and the signal processing IC 100 which are configured separately, so as not to have a monolithic structure.

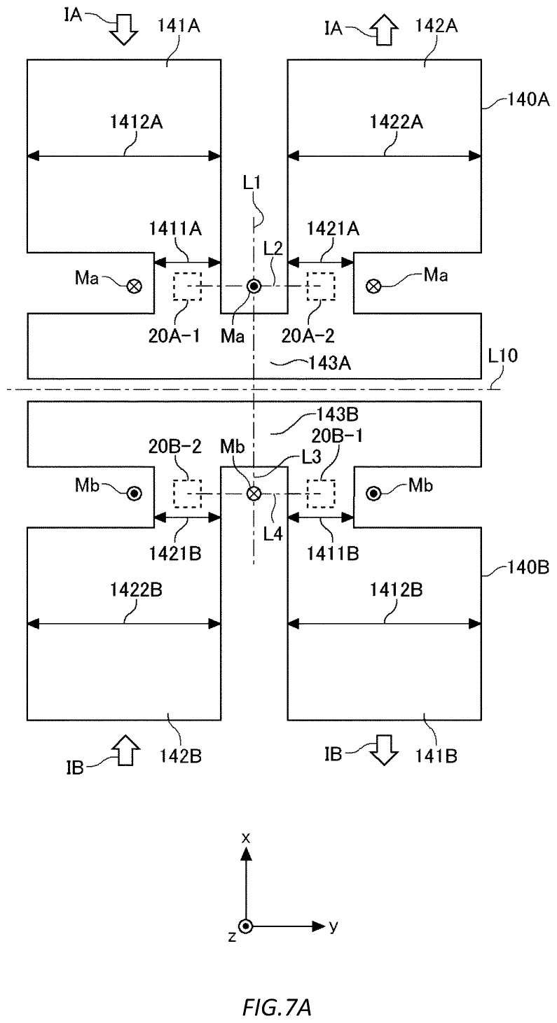

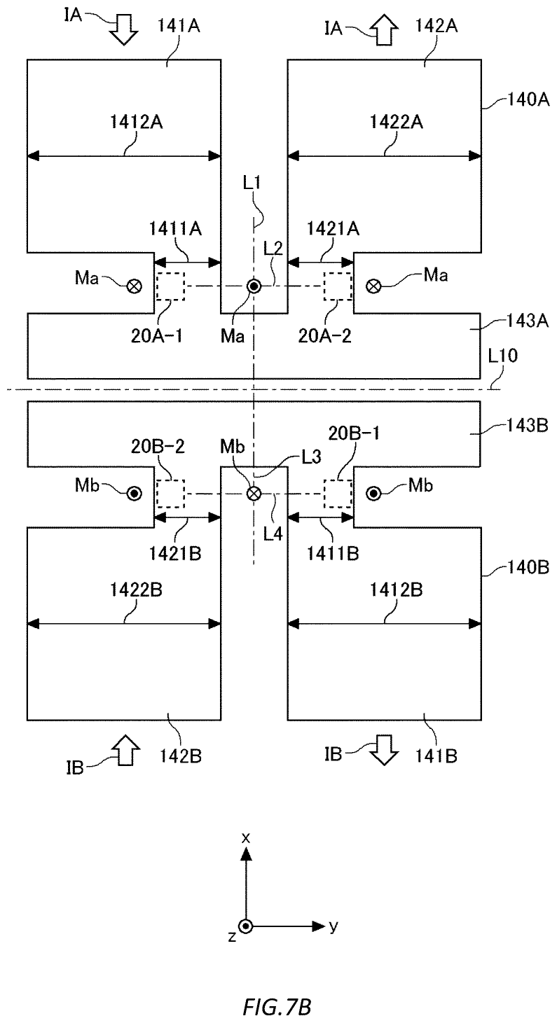

FIG. 7A is a diagram for describing the positional relationship between the magnetoelectric conversion element 20 and the current conductor 140A and the current conductor 140B.

The current conductor 140A has the same shape as that of the current conductor 140B. In the plan view, the current conductor 140A and the current conductor 140B are arranged in a positional relationship of a 180 degree rotation. In the plan view, the current conductor 140B is arranged at a position obtained by symmetrically moving the current conductor 140A with a symmetrical axis of a straight line L10 along the y direction. The magnetoelectric conversion element 20A-1 and the magnetoelectric conversion element 20A-2 are arranged to detect the magnetic field that is in the y axis direction on the xy plane and that is generated by the measuring target current flowing through the current conductor 140A. In the plan view, the magnetoelectric conversion element 20A-1 and the magnetoelectric conversion element 20A-2 may be arranged at positions overlapping with the current conductor 140A. The magnetoelectric conversion element 20B-1 and the magnetoelectric conversion element 20B-2 are arranged to detect the magnetic field that is in the y axis direction on the xy plane and that is generated by the measuring target current flowing through the current conductor 140B. In the plan view, the magnetoelectric conversion element 20B-1 and the magnetoelectric conversion element 20B-2 may be arranged at positions overlapping with the current conductor 140B.

The magnetoelectric conversion element 20A-1 and the magnetoelectric conversion element 20A-2 are arranged to face each other in the y axis direction. The magnetoelectric conversion element 20B-1 and the magnetoelectric conversion element 20B-2 are arranged to face each other in the y axis direction. In the plan view, the entire magnetosensitive surface of the magnetoelectric conversion element 20A-1 overlaps with the conductor portion 141A, and in the plan view, the entire magnetosensitive surface of the magnetoelectric conversion element 20A-2 may overlap with the conductor portion 142A. In the plan view, the entire magnetosensitive surface of the magnetoelectric conversion element 20B-1 overlaps with the conductor portion 141B, and in the plan view, the entire magnetosensitive surface of the magnetoelectric conversion element 20B-2 may overlap with the conductor portion 142B.

In the plan view, a shape constituted by the conductor portion 141A, the conductor portion 142A, and the conductor portion 143A which constitute the current conductor 140A, is line-symmetrical with the symmetrical axis of the perpendicular bisector L3 of the line segment L4 connecting the magnetoelectric conversion element 20B-1 and the magnetoelectric conversion element 20B-2, based on the positional relationship between the magnetoelectric conversion element 20B-1 and the magnetoelectric conversion element 20B-2. In the plan view, a shape constituted by the conductor portion 141B, the conductor portion 142B, and the conductor portion 143B is line-symmetrical with the symmetrical axis of the perpendicular bisector L1 of the line segment L2 connecting the magnetoelectric conversion element 20A-1 and the magnetoelectric conversion element 20A-2, based on the positional relationship between the magnetoelectric conversion element 20A-1 and the magnetoelectric conversion element 20A-2.

In the plan view, the conductor portion 141A includes a portion 1411A which overlaps with the magnetoelectric conversion element 20A-1, and a portion 1412A which is wider in the y axis direction than the portion 1411A which overlaps with the magnetoelectric conversion element 20A-1. In the plan view, the conductor portion 142A includes a portion 1421A which overlaps with the magnetoelectric conversion element 20A-2, and a portion 1422A which is wider in the y axis direction than the portion 1421A which overlaps with the magnetoelectric conversion element 20A-2. In the plan view, the conductor portion 141B includes a portion 1411B which overlaps with the magnetoelectric conversion element 20B-1, and a portion 1412B which is wider in the y axis direction than the portion 1411B which overlaps with the magnetoelectric conversion element 20B-1. In the plan view, the conductor portion 142B includes a portion 1421B which overlaps with the magnetoelectric conversion element 20B-2, and a portion 1422B which is wider in the y axis direction than the portion 1421B which overlaps with the magnetoelectric conversion element 20B-2. The narrow widths of the parts of the current conductors 140A and 140B which overlap with the magnetoelectric conversion element 20, make it possible for the magnetoelectric conversion element 20 to measure, with high sensitivity, the currents flowing through the current conductors 140A and 140B.

In the plan view, the magnetoelectric conversion element 20A-1 may be arranged at the center of the width of the portion 1411A of the conductor portion 141A, in the y axis direction, which overlaps with the magnetoelectric conversion element 20A-1. In the plan view, the magnetoelectric conversion element 20A-2 may be arranged at the center of the width of the portion 1421A of the conductor portion 142A, in the y axis direction, which overlaps with the magnetoelectric conversion element 20A-2. In the plan view, the magnetoelectric conversion element 20B-1 may be arranged at the center of the width of the portion 1411B of the conductor portion 141B, in the y axis direction, which overlaps with the magnetoelectric conversion element 20B-1. In the plan view, the magnetoelectric conversion element 20B-2 may be arranged at the center of the width of the portion 1421B of the conductor portion 142B, in the y axis direction, which overlaps with the magnetoelectric conversion element 20B-2. This makes it possible for the magnetoelectric conversion element 20 to measure, with higher sensitivity, the currents flowing through the current conductors 140A and 140B.

However, as shown in FIG. 7B, in the plan view, as long as the magnetoelectric conversion element 20 is arranged at a part of the current conductor 140A or the current conductor 140B which overlaps with the magnetoelectric conversion element 20, it may not be arranged at the center of the part.

In the current sensor 10 according to the second embodiment configured as described above, it is also possible to shorten a distance between the current conductor 140A and the current conductor 140B, while the conductor portion 143A and the conductor portion 143B are arranged to be spaced apart to face each other. In the plan view, the distance between parts at which the current conductor 140A and the current conductor 140B face each other, that is, between the conductor portion 143A and the conductor portion 143B, may be 2 mm or less and 0.1 mm or more. Therefore, it is possible to reduce a width of the sealing section 130 in the x axis direction, and it is possible to reduce a size of the current sensor 10 which is able to measure the measuring target current for two channels. A resin material that constitutes the sealing section 130 fills between the conductor portion 143A and the conductor portion 143B. Therefore, it is also possible to ensure insulation between the conductor portion 143A and the conductor portion 143B.

In an example of the current sensor 10 described in the present specification, a distance from the surface 130a to surface 130b in the sealing section 130 is 10 mm, and a distance from the surface 130c to the surface 130d is 20 mm. However, the current sensor 10 only needs to be of a sufficiently small type, and for example, the distance from the surface 130a to the surface 130b in the sealing section 130 may be from 3 mm and to 30 mm, and the distance from the surface 130c to the surface 130d may be from 5 mm and to 50 mm. Conversely, when the size of the current sensor 10 is reduced, it is preferable to minimize the length of the current conductor 140A and the current conductor 140B in the x axis direction, and to reduce the distance between parts at which the current conductor 140A and the current conductor 140B face each other, that is, between the conductor portion 143A and the conductor portion 143B.

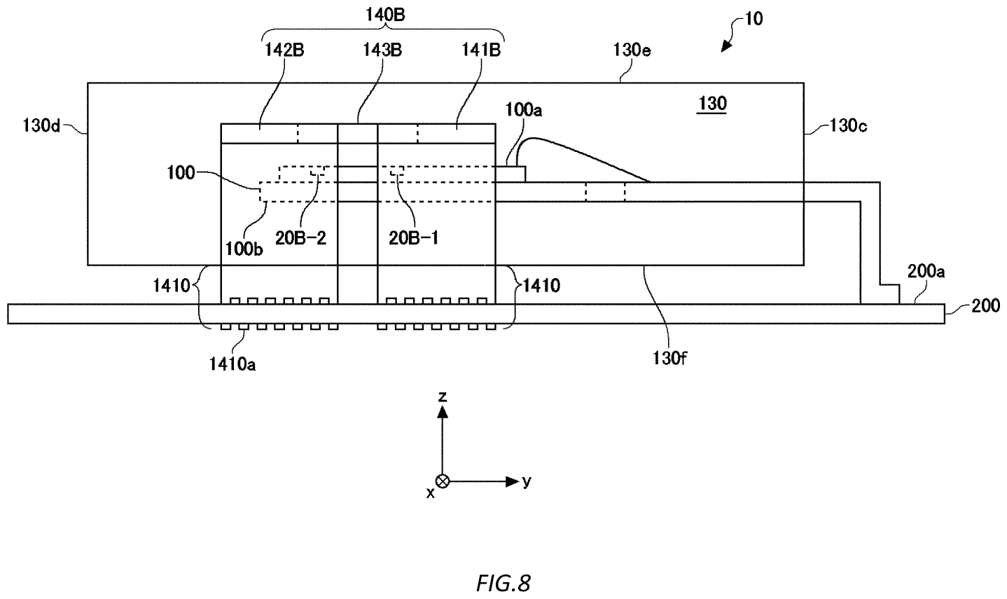

The current sensor 10 shown in FIG. 6A to FIG. 6C is an example of a front surface mounting type. However, the current sensor 10 may also be of an insertion mounting type in which the current conductor 140A and the current conductor 140B are inserted into the substrate 200. In the case of the insertion mounting type, when the extension portion 1410 is inserted into the substrate 200, it is good for a width of an edge of the extension portion 1410 to be narrower than a width of a part other than the edge of the extension portion 1410 to reliably ensure a space between the mounting surface 200a of the substrate 200 and the surface 130f of the sealing section 130. For example, as shown in FIG. 8, the edge of the extension portion 1410 may include the plurality of tooth portions 1410a aligned in a comb shape. A width of each of the plurality of tooth portions 1410a may be from 0.5 times to twice the thickness D of each of the conductor portion 141A, the conductor portion 142A, the conductor portion 141B, and the conductor portion 142B (shown in FIG. 6C). A cross-section of the plurality of tooth portions 1410a may be square. A distance between the sealing section 130 and the mounting surface 200a of the substrate 200 is preferably 1 mm or more. This makes it possible to more reliably ensure insulation between the sealing section 130 and the substrate 200.

By the way, in the case where the measuring target current is caused to flow through the current conductor 140A and the current conductor 140B, when resistance values of the current conductor 140A and the current conductor 140B are great, there is a possibility that the heat generated by the current conductor 140A and the current conductor 140B may change the electrical characteristic of the magnetoelectric conversion element 20, to affect a precision of the magnetic field detection of the magnetoelectric conversion element 20. Therefore, it is preferable for the resistance values of the current conductor 140A and the current conductor 140B to be as low as possible.

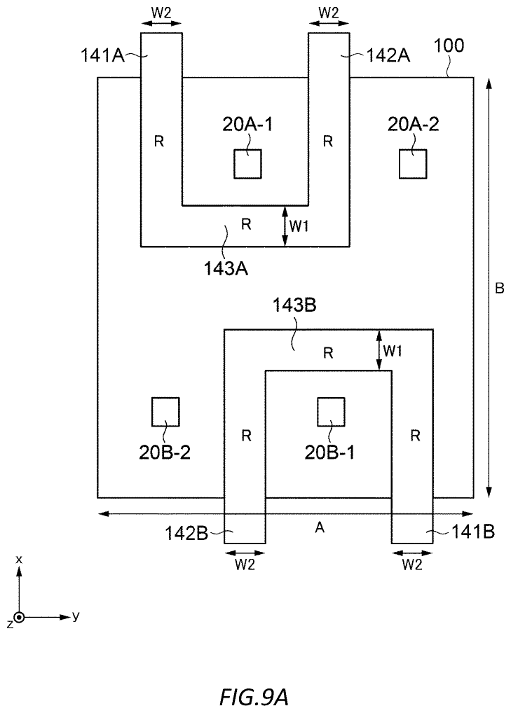

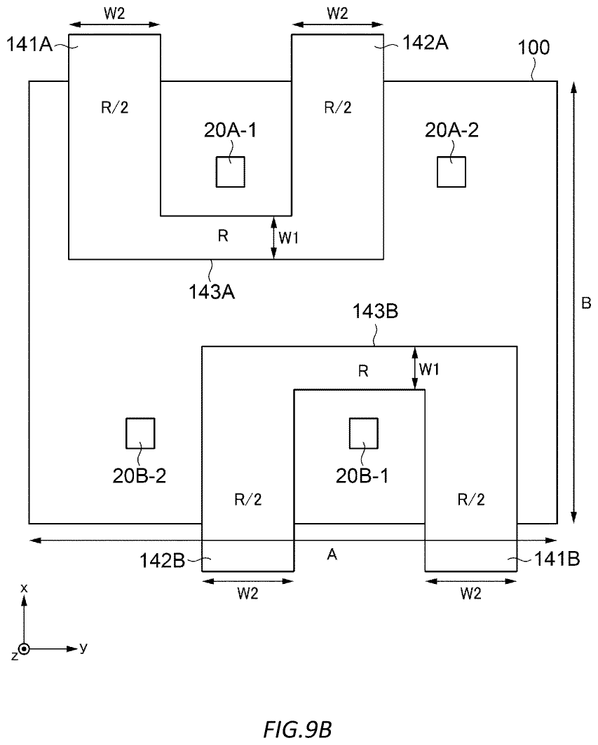

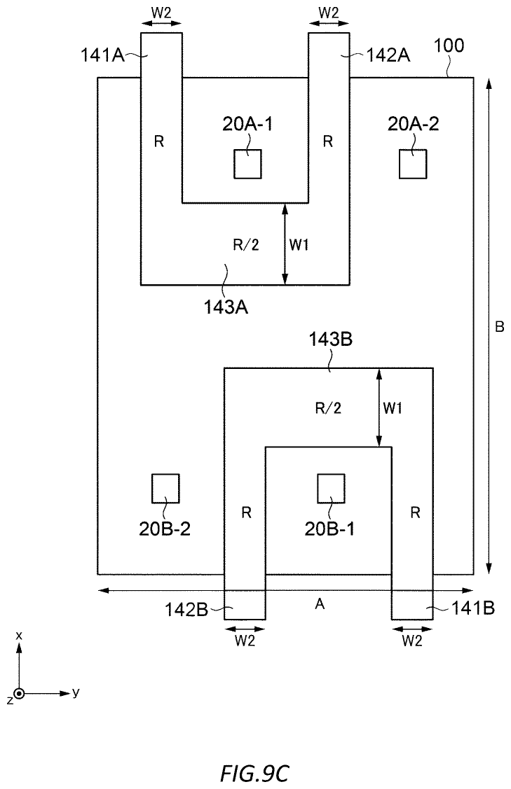

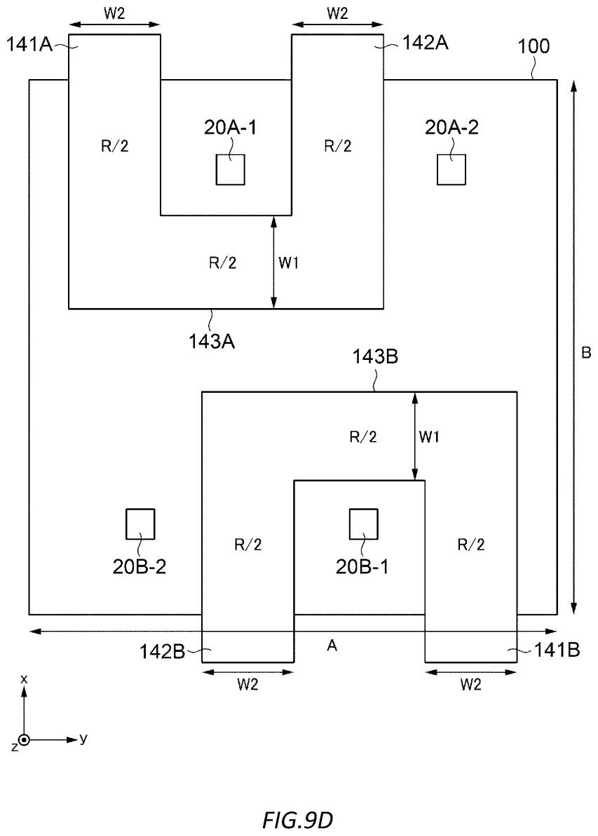

FIG. 9A shows a plan view of the signal processing IC 100, the magnetoelectric conversion element 20, and the current conductor 140A and the current conductor 140B, in an original case. In the original case, a width W1 of each of the conductor portions 143A, 143B, in the x axis direction, which constitute the current conductors 140A, 140B, is the same as a width W2 of each of the conductor portions 141A, 141B, and the conductor portions 142A, 142B in the y axis direction. In addition, the resistance values of: the conductor portions 141A, 141B; the conductor portions 142A, 142B; and the conductor portions 143A, 143B are the same as each other, and are set as R. The width of the signal processing IC 100 in the y axis direction is set as A, and the width of the signal processing IC 100 in the x axis direction is set as B.

FIG. 9B shows a plan view of the signal processing IC 100, the magnetoelectric conversion element 20, and the current conductor 140A and the current conductor 140B, in a case 1. In the case 1, the width W1 of each of the conductor portions 143A, 143B, in the x axis direction, which constitute the current conductors 140A, 140B, is narrower the width W2 of each of the conductor portions 141A, 141B, and the conductor portions 142A, 142B in the y axis direction. The width W2 is twice the width W1. The resistance values of the conductor portions 143A, 143B are R, and the resistance values of the conductor portions 141A, 141B, and the conductor portions 142A, 142B are R/2. That is, the resistance values of the conductor portions 143A, 143B are twice the resistance values of the conductor portions 141A, 141B, and the conductor portions 142A, 142B.

FIG. 9C shows a plan view of the signal processing IC 100, the magnetoelectric conversion element 20, and the current conductor 140A and the current conductor 140B, in a case 2. In the case 2, the width W1 of each of the conductor portions 143A, 143B, in the x axis direction, which constitute the current conductors 140A, 140B, is wider than the width W2 of each of the conductor portions 141A, 141B, and the conductor portions 142A, 142B in the y axis direction. The width W2 is half of the width W1. The resistance values of the conductor portions 143A, 143B are R/2, and the resistance values of the conductor portions 141A, 141B, and the conductor portions 142A, 142B are R. That is, the resistance values of the conductor portions 143A, 143B are half of the resistance values of the conductor portions 141A, 141B, and the conductor portions 142A, 142B.

FIG. 9D shows a plan view of the signal processing IC 100, the magnetoelectric conversion element 20, and the current conductor 140A and the current conductor 140B, in a case 3. In the case 3, the width W1 of each of the conductor portions 143A, 143B, in the x axis direction, which constitute the current conductors 140A, 140B, is the same as the width W2 of each of the conductor portions 141A, 141B, and the conductor portions 142A, 142B in the y axis direction. The width W1 and the width W2 in the case 3 are twice the width W1 and the width W2 in the original case. The resistance values of the conductor portions 143A, 143B are R/2, and the resistance values of the conductor portions 141A, 141B, and the conductor portions 142A, 142B are R/2.

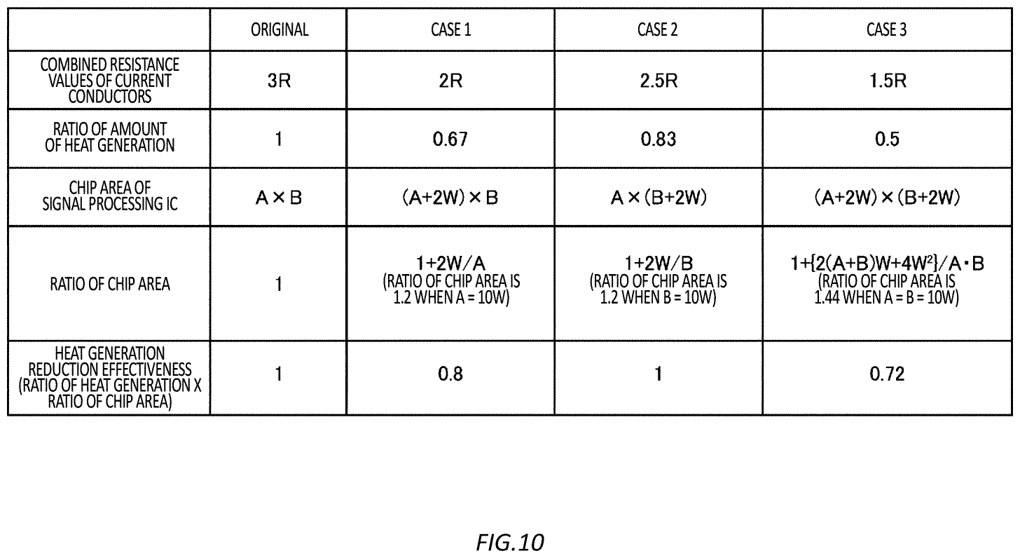

FIG. 10 is a table showing heat generation reduction effectiveness in the original case, the case 1, the case 2, and the case 3. The heat generation reduction effectiveness is a value obtained by multiplying a ratio of an amount of the heat generation by a ratio of a chip area. In FIG. 10, the ratio of the amount of the heat generation in the original case is set to 1, and the ratio of the amount of the heat generation in each of the case 1, the case 2, and the case 3 is shown. In addition, in FIG. 10, the ratio of the chip area in the original case is set to 1, and the ratio of the chip area in each of the case 1, the case 2, and the case 3 is shown. The smaller a value of the heat generation reduction effectiveness is, the more it is possible to realize the current sensor 10 in which the heat generation is small by the reduction in size and cost. That is, it is preferable that: the width W1 of each of the conductor portion 143A and the conductor portion 143B in the x axis direction, is the same as the width W2 of each of the conductor portion 141A, the conductor portion 142A, the conductor portion 141B, and the conductor portion 142B in the y axis direction; or the width W1 is narrower than the width W2. This makes it possible to realize the current sensor 10 in which the heat generation is small by the reduction in size and cost.

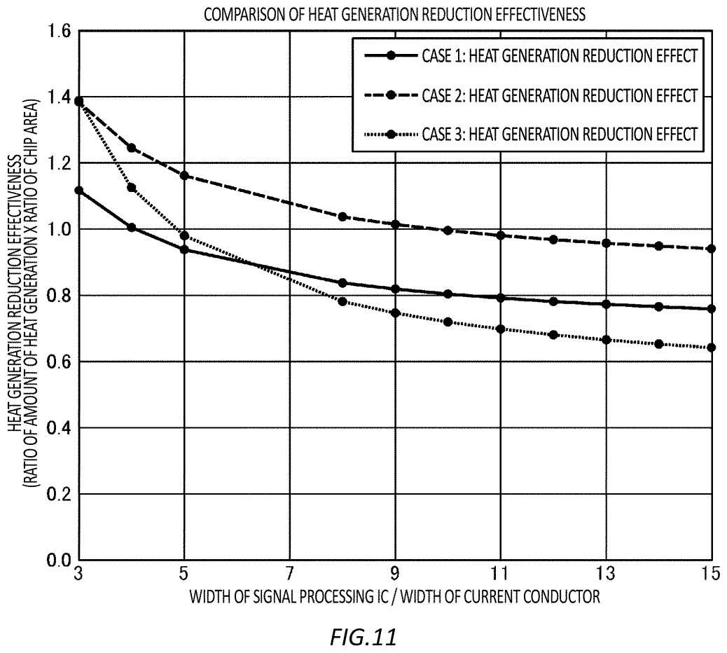

FIG. 11 shows a degree of the heat generation reduction effectiveness in accordance with ratios of a width of the signal processing IC 100 to a width of the current conductors 140A, 140B in the case 1, the case 2, and the case 3. As shown in FIG. 11, when the width of the signal processing IC 100 is smaller than six times the width of the current conductors 140A, 140B, the heat generation reduction effectiveness is the highest in the case 1. On the other hand, when the width of the signal processing IC 100 is greater than six times the width of the current conductors 140A, 140B, the heat generation reduction effectiveness is the highest in the case 3. Here, in a case where it is required that an occupying ratio of a circuit area is small, and a chip area necessary for a sensor arrangement is reduced to be as small as possible, the case 1 is more effective than the case 3. Note that a case where the chip area dominates the circuit area, is not limited to this.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### (Other Possible Items)

### (Item 1)

A current sensor including: a first current conductor through which a first measuring target current flows;
a first magnetoelectric conversion element which detects a magnetic field that is generated by the first measuring target current;
a second current conductor through which a second measuring target current flows;
a second magnetoelectric conversion element which detects a magnetic field that is generated by the second measuring target current;
a signal processing IC that processes a signal that is output from at least one of the first magnetoelectric conversion element or the second magnetoelectric conversion element;
a signal conductor which is electrically connected to the signal processing IC and transmits a signal that is output from the signal processing IC; and
a sealing section which seals a part of the first current conductor, the first magnetoelectric conversion element, a part of the second current conductor, the second magnetoelectric conversion element, the signal processing IC, and a part of the signal conductor, in which
at least one of the first magnetoelectric conversion element or the second magnetoelectric conversion element is arranged on a circuit surface of the signal processing IC,
in a plan view, the first current conductor and the second current conductor face each other at least partially at a position overlapping with the signal processing IC,
in a cross-sectional view, within the sealing section, each of the first current conductor and the second current conductor is at a different height from that of the signal conductor,
between the first current conductor and the second current conductor, a resin material that constitutes the sealing section is arranged,
a part of the first current conductor is exposed from a first surface of the sealing section,
a part of the second current conductor is exposed from a second surface which is opposite to the first surface of the sealing section in a first direction, and
a part of the signal conductor is exposed from a third surface which is different from the first surface and the second surface of the sealing section.

### (Item 2)

The current sensor according to item 1, in which in the plan view, a distance between parts at which the first current conductor and the second current conductor face each other is 2 mm or less and 0.1 mm or more.

### (Item 3)

The current sensor according to item 1, in which from a fourth surface of the sealing section which is opposite to the third surface in a second direction intersecting the first direction, a part of the signal conductor is not exposed.

### (Item 4)

The current sensor according to item 1, further including: a third magnetoelectric conversion element which is arranged to face the first magnetoelectric conversion element across a part of the first current conductor, in the plan view; and
a fourth magnetoelectric conversion element which is arranged to face the second magnetoelectric conversion element across a part of the second current conductor, in the plan view, in which
the first magnetoelectric conversion element, the second magnetoelectric conversion element, the third magnetoelectric conversion element, and the fourth magnetoelectric conversion element are arranged on the circuit surface of the signal processing IC.

### (Item 5)

The current sensor according to item 4, in which the first magnetoelectric conversion element, the second magnetoelectric conversion element, the third magnetoelectric conversion element, and the fourth magnetoelectric conversion element are built in a chip which constitutes the signal processing IC.

### (Item 6)

The current sensor according to item 4, in which the first magnetoelectric conversion element, the second magnetoelectric conversion element, the third magnetoelectric conversion element, and the fourth magnetoelectric conversion element are constituted by chips separate from a chip which constitutes the signal processing IC.

### (Item 7)

The current sensor according to item 6, in which the first magnetoelectric conversion element, the second magnetoelectric conversion element, the third magnetoelectric conversion element, and the fourth magnetoelectric conversion element are electrically connected to the signal processing IC via wires, and
in the plan view, the wires are electrically connected to the first magnetoelectric conversion element and the second magnetoelectric conversion element, and the signal processing IC, without crossing over the first current conductor and the second current conductor.

### (Item 8)

The current sensor according to item 1, in which in the plan view, the first current conductor or the second current conductor, the signal processing IC, and the signal conductor overlap with each other at least partially.

### (Item 9)

The current sensor according to item 1, in which the first current conductor and the second current conductor are constituted by a first lead frame, and
the signal conductor is constituted by a second lead frame.

### (Item 10)

The current sensor according to item 1, in which in a direction intersecting the circuit surface of the signal processing IC,
the first current conductor is at a same height as that of the second current conductor within the sealing section, and
the signal conductor is at a height different from those of the first current conductor and the second current conductor.

### (Item 11)

The current sensor according to item 1, in which in the plan view, the first current conductor includes a first conductor portion and a second conductor portion which extend in the first direction and are spaced apart from each other in a second direction intersecting the first direction, and a third conductor portion which extends in the second direction and links the first conductor portion to the second conductor portion,
in the plan view, the second current conductor includes a fourth conductor portion and a fifth conductor portion which extend in the first direction and are spaced apart from each other in the second direction, and a sixth conductor portion which extends in the second direction and links the fourth conductor portion to the fifth conductor portion,
the first conductor portion and the second conductor portion are partially exposed from the first surface of the sealing section, and
the fourth conductor portion and the fifth conductor portion are partially exposed from the second surface of the sealing section.

### (Item 12)

The current sensor according to item 1, in which in the plan view, the first magnetoelectric conversion element is surrounded by the first conductor portion, the second conductor portion, and the third conductor portion,
in the plan view, the second magnetoelectric conversion element is surrounded by the fourth conductor portion, the fifth conductor portion, and the sixth conductor portion, and
a first width of each of the third conductor portion and the sixth conductor portion in the first direction, is the same as a second width of each of the first conductor portion, the second conductor portion, the fourth conductor portion, and the fifth conductor portion in the second direction, or the first width is narrower than the second width.

### (Item 13)

The current sensor according to item 11, in which in the plan view, the third conductor portion and the sixth conductor portion are spaced apart to face each other, and a resin material that constitutes the sealing section fills between the third conductor portion and the sixth conductor portion.

### (Item 14)

The current sensor according to item 13, in which in the plan view, a distance between parts at which the third conductor portion and the sixth conductor portion face each other is 2 mm or less and 0.1 mm or more.

### (Item 15)

The current sensor according to item 11, further including: a third magnetoelectric conversion element which is arranged to face the first magnetoelectric conversion element across a part of the first conductor portion in the second direction, in the plan view; and
a fourth magnetoelectric conversion element which is arranged to face the second magnetoelectric conversion element across a part of the fifth conductor portion in the second direction, in the plan view, in which
in the plan view, at least a part of the third magnetoelectric conversion element is positioned in a region that is surrounded by the first current conductor,
in the plan view, at least a part of the fourth magnetoelectric conversion element is positioned in a region that is surrounded by the second current conductor,
in the plan view, a distance between the first magnetoelectric conversion element and the sixth conductor portion, is equal to a distance between the third magnetoelectric conversion element and the sixth conductor portion, and
in the plan view, a distance between the second magnetoelectric conversion element and the third conductor portion, is equal to a distance between the fourth magnetoelectric conversion element and the third conductor portion.

### (Item 16)

The current sensor according to item 11, further including: a third magnetoelectric conversion element which is arranged to face the first magnetoelectric conversion element across the second conductor portion, in the plan view; and
a fourth magnetoelectric conversion element which is arranged to face the second magnetoelectric conversion element across the fourth conductor portion, in the plan view, in which
in the plan view, the first magnetoelectric conversion element is positioned in a region that is surrounded by the first current conductor,
in the plan view, the second magnetoelectric conversion element is positioned in a region that is surrounded by the second current conductor,
in the plan view, a distance between the first magnetoelectric conversion element and the sixth conductor portion, is equal to a distance between the third magnetoelectric conversion element and the sixth conductor portion,
in the plan view, a distance between the second magnetoelectric conversion element and the third conductor portion, is equal to a distance between the fourth magnetoelectric conversion element and the third conductor portion, and
the first magnetoelectric conversion element, the second magnetoelectric conversion element, the third magnetoelectric conversion element, and the fourth magnetoelectric conversion element have sensitivity axes in a third direction intersecting the first direction and the second direction.

### (Item 17)

The current sensor according to item 16, in which in the plan view, the first magnetoelectric conversion element is positioned on an extension line along which the fifth conductor portion extends, in the plan view, the third magnetoelectric conversion element is positioned on an extension line along which the fourth conductor portion extends, in the plan view, the second magnetoelectric conversion element is positioned on an extension line along which the second conductor portion extends, and in the plan view, the fourth magnetoelectric conversion element is positioned on an extension line along which the first conductor portion extends.

### (Item 18)

The current sensor according to item 17, in which in the plan view, the first magnetoelectric conversion element is positioned on a perpendicular bisector of a line segment connecting the second magnetoelectric conversion element and the fourth magnetoelectric conversion element, and in the plan view, the second magnetoelectric conversion element is positioned on a perpendicular bisector of a line segment connecting the first magnetoelectric conversion element and the third magnetoelectric conversion element.

### (Item 19)

The current sensor according to item 18, in which in the plan view, a shape constituted by the first conductor portion, the second conductor portion, and the third conductor portion is line-symmetrical with a symmetrical axis of a perpendicular bisector of a line segment connecting the second magnetoelectric conversion element and the fourth magnetoelectric conversion element, and in the plan view, a shape constituted by the fourth conductor portion, the fifth conductor portion, and the sixth conductor portion is line-symmetrical with a symmetrical axis of a perpendicular bisector of a line segment connecting the first magnetoelectric conversion element and the third magnetoelectric conversion element.

### (Item 20)

The current sensor according to item 16, in which the first magnetoelectric conversion element, the second magnetoelectric conversion element, the third magnetoelectric conversion element, and the fourth magnetoelectric conversion element have sensitivity axes in a direction intersecting magnetosensitive surfaces.

### (Item 21)

The current sensor according to item 20, in which the first magnetoelectric conversion element, the second magnetoelectric conversion element, the third magnetoelectric conversion element, and the fourth magnetoelectric conversion element are Hall elements.

### (Item 22)

The current sensor according to item 11, in which the first current conductor has a same shape as that of the second current conductor, and
in the plan view, the second current conductor is arranged at a position obtained by symmetrically moving the first current conductor with a symmetrical axis of a straight line along the second direction,
the current sensor further including:
a third magnetoelectric conversion element which is arranged to face the first magnetoelectric conversion element in the second direction; and
a fourth magnetoelectric conversion element which is arranged to face the second magnetoelectric conversion element in the second direction,
in the plan view, an entire magnetosensitive surface of the first magnetoelectric conversion element overlaps with the first conductor portion,
in the plan view, an entire magnetosensitive surface of the third magnetoelectric conversion element overlaps with the second conductor portion,
in the plan view, an entire magnetosensitive surface of the second magnetoelectric conversion element overlaps with the fourth conductor portion,
in the plan view, an entire magnetosensitive surface of the fourth magnetoelectric conversion element overlaps with the fifth conductor portion, and
the first magnetoelectric conversion element, the second magnetoelectric conversion element, the third magnetoelectric conversion element, and the fourth magnetoelectric conversion element have sensitivity axes in the second direction.

### (Item 23)

The current sensor according to item 22, in which in the plan view, the first magnetoelectric conversion element is arranged at a center of a width of a portion of the first conductor portion, in the second direction, which overlaps with the first magnetoelectric conversion element,
in the plan view, the third magnetoelectric conversion element is arranged at a center of a width of a portion of the second conductor portion, in the second direction, which overlaps with the third magnetoelectric conversion element,
in the plan view, the second magnetoelectric conversion element is arranged at a center of a width of a portion of the fourth conductor portion, in the second direction, which overlaps with the second magnetoelectric conversion element, and
in the plan view, the fourth magnetoelectric conversion element is arranged at a center of a width of a portion of the fifth conductor portion, in the second direction, which overlaps with the fourth magnetoelectric conversion element.

### (Item 24)

The current sensor according to item 22, in which in the plan view, the first conductor portion includes a portion which overlaps with the first magnetoelectric conversion element, and a portion which is wider in the second direction than the portion which overlaps with the first magnetoelectric conversion element,
in the plan view, the second conductor portion includes a portion which overlaps with the third magnetoelectric conversion element, and a portion which is wider in the second direction than the portion which overlaps with the third magnetoelectric conversion element,
in the plan view, the fourth conductor portion includes a portion which overlaps with the second magnetoelectric conversion element, and a portion which is wider in the second direction than the portion which overlaps with the second magnetoelectric conversion element, and
in the plan view, the fifth conductor portion includes a portion which overlaps with the fourth magnetoelectric conversion element, and a portion which is wider in the second direction than the portion which overlaps with the fourth magnetoelectric conversion element.

### (Item 25)

The current sensor according to item 21, the first magnetoelectric conversion element, the second magnetoelectric conversion element, the third magnetoelectric conversion element, and the fourth magnetoelectric conversion element are magnetoresistance elements using a magnetoresistive effect.

### (Item 26)

The current sensor according to item 25, in which the first magnetoelectric conversion element, the second magnetoelectric conversion element, the third magnetoelectric conversion element, and the fourth magnetoelectric conversion element are built in a chip which constitutes the signal processing IC.

### (Item 27)

The current sensor according to item 11, in which parts of the first conductor portion and the second conductor portion that are respectively exposed from the first surface of the sealing section, and parts of the fourth conductor portion and the fifth conductor portion that are respectively exposed from the second surface of the sealing section, have extension portions which extend further in a third direction intersecting the first direction and the second direction, from a surface of the sealing section which faces a surface on an opposite side of the circuit surface of the signal processing IC.

### (Item 28)

The current sensor according to item 27, in which a width of an edge of an extension portion, which is included in the extension portions, is narrower than a width of a part other than the edge of the extension portion.

### (Item 29)

The current sensor according to item 27, in which an edge of an extension portion, which is included in the extension portions, includes a plurality of tooth portions aligned in a comb shape, and
a width of each of the plurality of tooth portions is from 0.5 times to twice a thickness of each of the first conductor portion, the second conductor portion, the fourth conductor portion, and the fifth conductor portion.

### (Item 30)

A current sensor module including: the current sensor according to item 27; and
a substrate in which the current sensor is arranged on a mounting surface, in which
by an extension portion, which is included in the extension portions, being fixed to the mounting surface of the substrate, the sealing section is positioned above the mounting surface.

### (Item 31)

The current sensor module according to item 30, in which a width of an edge of the extension portion is narrower than a width of a part other than the edge of the extension portion.

### (Item 32)

The current sensor module according to item 30, in which an edge of the extension portion includes a plurality of tooth portions aligned in a comb shape, and a width of each of the plurality of tooth portions is from 0.5 times to twice a thickness of each of the first conductor portion, the second conductor portion, the fourth conductor portion, and the fifth conductor portion.

### (Item 33)

The current sensor module according to item 30, in which a distance between the mounting surface of the substrate, and a surface of the sealing section which faces the mounting surface, is 1 mm or more.

### EXPLANATION OF REFERENCES

10: current sensor
20, 20A-1, 20A-2, 20B-1, 20B-2: magnetoelectric conversion element
22, 108: wire
100: signal processing IC
130: sealing section
140A, 140B: current conductor
141A, 142A, 143A: conductor portion
141B, 142B, 143B: conductor portion
150: signal conductor
151: support section
152: terminal section
200: substrate
1410: extension portion
1410a: tooth portion.

What is claimed is:

1. A current sensor comprising:
a first current conductor through which a first measuring target current flows;
a first magnetoelectric conversion element which detects a magnetic field that is generated by the first measuring target current;
a second current conductor through which a second measuring target current flows;
a second magnetoelectric conversion element which detects a magnetic field that is generated by the second measuring target current;
a signal processing IC that processes a signal that is output from at least one of the first magnetoelectric conversion element or the second magnetoelectric conversion element;
a signal conductor which is electrically connected to the signal processing IC and transmits a signal that is output from the signal processing IC; and
a sealing section which seals a part of the first current conductor, the first magnetoelectric conversion element, a part of the second current conductor, the second magnetoelectric conversion element, the signal processing IC, and a part of the signal conductor, wherein
at least one of the first magnetoelectric conversion element or the second magnetoelectric conversion element is arranged on a circuit surface of the signal processing IC,
in a plan view, the first current conductor and the second current conductor face each other at least partially at a position overlapping with the signal processing IC,
in a cross-sectional view, within the sealing section, each of the first current conductor and the second current conductor is at a different height from that of the signal conductor,
between the first current conductor and the second current conductor, a resin material that constitutes the sealing section is arranged,
a part of the first current conductor is exposed from a first surface of the sealing section,
a part of the second current conductor is exposed from a second surface which is opposite to the first surface of the sealing section in a first direction, and
a part of the signal conductor is exposed from a third surface which is different from the first surface and the second surface of the sealing section.

2. The current sensor according to claim 1, wherein in the plan view, a distance between parts at which the first current conductor and the second current conductor face each other is 2 mm or less and 0.1 mm or more.

3. The current sensor according to claim 1, wherein from a fourth surface of the sealing section which is opposite to the third surface in a second direction intersecting the first direction, a part of the signal conductor is not exposed.

4. The current sensor according to claim 1, further comprising:
a third magnetoelectric conversion element which is arranged to face the first magnetoelectric conversion element across a part of the first current conductor, in the plan view; and
a fourth magnetoelectric conversion element which is arranged to face the second magnetoelectric conversion element across a part of the second current conductor, in the plan view, wherein
the first magnetoelectric conversion element, the second magnetoelectric conversion element, the third magnetoelectric conversion element, and the fourth magnetoelectric conversion element are arranged on the circuit surface of the signal processing IC.

5. The current sensor according to claim 4, wherein the first magnetoelectric conversion element, the second magnetoelectric conversion element, the third magnetoelectric conversion element, and the fourth magnetoelectric conversion element are built in a chip which constitutes the signal processing IC.

6. The current sensor according to claim 4, wherein the first magnetoelectric conversion element, the second magnetoelectric conversion element, the third magnetoelectric conversion element, and the fourth magnetoelectric conversion element are constituted by chips separate from a chip which constitutes the signal processing IC.

7. The current sensor according to claim 6, wherein
the first magnetoelectric conversion element, the second magnetoelectric conversion element, the third magnetoelectric conversion element, and the fourth magnetoelectric conversion element are electrically connected to the signal processing IC via wires, and
in the plan view, the wires are electrically connected to the first magnetoelectric conversion element and the second magnetoelectric conversion element, and the signal processing IC, without crossing over the first current conductor and the second current conductor.

8. The current sensor according to claim 1, wherein in the plan view, the first current conductor or the second current conductor, the signal processing IC, and the signal conductor overlap with each other at least partially.

9. The current sensor according to claim 1, wherein
the first current conductor and the second current conductor are constituted by a first lead frame, and
the signal conductor is constituted by a second lead frame.

10. The current sensor according to claim 1, wherein
in a direction intersecting the circuit surface of the signal processing IC,
the first current conductor is at a same height as that of the second current conductor within the sealing section, and
the signal conductor is at a height different from those of the first current conductor and the second current conductor.

11. The current sensor according to claim 1, wherein
in the plan view, the first current conductor includes a first conductor portion and a second conductor portion which extend in the first direction and are spaced apart from each other in a second direction intersecting the first direction, and a third conductor portion which extends in the second direction and links the first conductor portion to the second conductor portion,
in the plan view, the second current conductor includes a fourth conductor portion and a fifth conductor portion which extend in the first direction and are spaced apart from each other in the second direction, and a sixth conductor portion which extends in the second direction and links the fourth conductor portion to the fifth conductor portion,
the first conductor portion and the second conductor portion are partially exposed from the first surface of the sealing section, and
the fourth conductor portion and the fifth conductor portion are partially exposed from the second surface of the sealing section.

12. The current sensor according to claim 11, wherein
in the plan view, the first magnetoelectric conversion element is surrounded by the first conductor portion, the second conductor portion, and the third conductor portion,
in the plan view, the second magnetoelectric conversion element is surrounded by the fourth conductor portion, the fifth conductor portion, and the sixth conductor portion, and
a first width of each of the third conductor portion and the sixth conductor portion in the first direction, is the same as a second width of each of the first conductor portion, the second conductor portion, the fourth conductor portion, and the fifth conductor portion in the second direction, or the first width is narrower than the second width.

13. The current sensor according to claim 11, wherein in the plan view, the third conductor portion and the sixth conductor portion are spaced apart to face each other, and a resin material that constitutes the sealing section fills between the third conductor portion and the sixth conductor portion.

14. The current sensor according to claim 13, wherein in the plan view, a distance between parts at which the third conductor portion and the sixth conductor portion face each other is 2 mm or less and 0.1 mm or more.

15. The current sensor according to claim 11, further comprising:
a third magnetoelectric conversion element which is arranged to face the first magnetoelectric conversion element across a part of the first conductor portion in the second direction, in the plan view; and
a fourth magnetoelectric conversion element which is arranged to face the second magnetoelectric conversion element across a part of the fifth conductor portion in the second direction, in the plan view, wherein
in the plan view, at least a part of the third magnetoelectric conversion element is positioned in a region that is surrounded by the first current conductor,
in the plan view, at least a part of the fourth magnetoelectric conversion element is positioned in a region that is surrounded by the second current conductor,
in the plan view, a distance between the first magnetoelectric conversion element and the sixth conductor portion, is equal to a distance between the third magnetoelectric conversion element and the sixth conductor portion, and
in the plan view, a distance between the second magnetoelectric conversion element and the third conductor portion, is equal to a distance between the fourth magnetoelectric conversion element and the third conductor portion.

16. The current sensor according to claim 11, further comprising:
a third magnetoelectric conversion element which is arranged to face the first magnetoelectric conversion element across the second conductor portion, in the plan view; and
a fourth magnetoelectric conversion element which is arranged to face the second magnetoelectric conversion element across the fourth conductor portion, in the plan view, wherein
in the plan view, the first magnetoelectric conversion element is positioned in a region that is surrounded by the first current conductor,
in the plan view, the second magnetoelectric conversion element is positioned in a region that is surrounded by the second current conductor,
in the plan view, a distance between the first magnetoelectric conversion element and the sixth conductor portion, is equal to a distance between the third magnetoelectric conversion element and the sixth conductor portion,
in the plan view, a distance between the second magnetoelectric conversion element and the third conductor portion, is equal to a distance between the fourth magnetoelectric conversion element and the third conductor portion, and
the first magnetoelectric conversion element, the second magnetoelectric conversion element, the third magnetoelectric conversion element, and the fourth magnetoelectric conversion element have sensitivity axes in a third direction intersecting the first direction and the second direction.

17. The current sensor according to claim 16, wherein
in the plan view, the first magnetoelectric conversion element is positioned on an extension line along which the fifth conductor portion extends,
in the plan view, the third magnetoelectric conversion element is positioned on an extension line along which the fourth conductor portion extends,
in the plan view, the second magnetoelectric conversion element is positioned on an extension line along which the second conductor portion extends, and
in the plan view, the fourth magnetoelectric conversion element is positioned on an extension line along which the first conductor portion extends.

18. The current sensor according to claim 17, wherein
in the plan view, the first magnetoelectric conversion element is positioned on a perpendicular bisector of a line segment connecting the second magnetoelectric conversion element and the fourth magnetoelectric conversion element, and
in the plan view, the second magnetoelectric conversion element is positioned on a perpendicular bisector of a line segment connecting the first magnetoelectric conversion element and the third magnetoelectric conversion element.

19. The current sensor according to claim 18, wherein
in the plan view, a shape constituted by the first conductor portion, the second conductor portion, and the third conductor portion is line-symmetrical with a symmetrical axis of a perpendicular bisector of a line segment connecting the second magnetoelectric conversion element and the fourth magnetoelectric conversion element, and
in the plan view, a shape constituted by the fourth conductor portion, the fifth conductor portion, and the sixth conductor portion is line-symmetrical with a symmetrical axis of a perpendicular bisector of a line segment connecting the first magnetoelectric conversion element and the third magnetoelectric conversion element.

20. The current sensor according to claim 16, wherein the first magnetoelectric conversion element, the second magnetoelectric conversion element, the third magnetoelectric conversion element, and the fourth magnetoelectric conversion element have sensitivity axes in a direction intersecting magnetosensitive surfaces.

21. The current sensor according to claim 20, wherein the first magnetoelectric conversion element, the second magnetoelectric conversion element, the third magnetoelectric conversion element, and the fourth magnetoelectric conversion element are Hall elements.

22. The current sensor according to claim 11, wherein
the first current conductor has a same shape as that of the second current conductor, and
in the plan view, the second current conductor is arranged at a position obtained by symmetrically moving the first current conductor with a symmetrical axis of a straight line along the second direction,
the current sensor further comprising:
a third magnetoelectric conversion element which is arranged to face the first magnetoelectric conversion element in the second direction; and
a fourth magnetoelectric conversion element which is arranged to face the second magnetoelectric conversion element in the second direction,
in the plan view, an entire magnetosensitive surface of the first magnetoelectric conversion element overlaps with the first conductor portion,
in the plan view, an entire magnetosensitive surface of the third magnetoelectric conversion element overlaps with the second conductor portion,
in the plan view, an entire magnetosensitive surface of the second magnetoelectric conversion element overlaps with the fourth conductor portion,
in the plan view, an entire magnetosensitive surface of the fourth magnetoelectric conversion element overlaps with the fifth conductor portion, and
the first magnetoelectric conversion element, the second magnetoelectric conversion element, the third magnetoelectric conversion element, and the fourth magnetoelectric conversion element have sensitivity axes in the second direction.

23. The current sensor according to claim 22, wherein
in the plan view, the first magnetoelectric conversion element is arranged at a center of a width of a portion of the first conductor portion, in the second direction, which overlaps with the first magnetoelectric conversion element,
in the plan view, the third magnetoelectric conversion element is arranged at a center of a width of a portion of the second conductor portion, in the second direction, which overlaps with the third magnetoelectric conversion element,
in the plan view, the second magnetoelectric conversion element is arranged at a center of a width of a portion of the fourth conductor portion, in the second direction, which overlaps with the second magnetoelectric conversion element, and
in the plan view, the fourth magnetoelectric conversion element is arranged at a center of a width of a portion of the fifth conductor portion, in the second direction, which overlaps with the fourth magnetoelectric conversion element.

24. The current sensor according to claim 22, wherein
in the plan view, the first conductor portion includes a portion which overlaps with the first magnetoelectric conversion element, and a portion which is wider in the second direction than the portion which overlaps with the first magnetoelectric conversion element,
in the plan view, the second conductor portion includes a portion which overlaps with the third magnetoelectric conversion element, and a portion which is wider in the second direction than the portion which overlaps with the third magnetoelectric conversion element,
in the plan view, the fourth conductor portion includes a portion which overlaps with the second magnetoelectric conversion element, and a portion which is wider in the second direction than the portion which overlaps with the second magnetoelectric conversion element, and
in the plan view, the fifth conductor portion includes a portion which overlaps with the fourth magnetoelectric conversion element, and a portion which is wider in the second direction than the portion which overlaps with the fourth magnetoelectric conversion element.

25. The current sensor according to claim 21, wherein the first magnetoelectric conversion element, the second magnetoelectric conversion element, the third magnetoelectric conversion element, and the fourth magnetoelectric conversion element are magnetoresistance elements using a magnetoresistive effect.

26. The current sensor according to claim 25, wherein the first magnetoelectric conversion element, the second magnetoelectric conversion element, the third magnetoelectric conversion element, and the fourth magnetoelectric conversion element are built in a chip which constitutes the signal processing IC.

27. The current sensor according to claim 11, wherein parts of the first conductor portion and the second conductor portion that are respectively exposed from the first surface of the sealing section, and parts of the fourth conductor portion and the fifth conductor portion that are respectively exposed from the second surface of the sealing section, have extension portions which extend further in a third direction intersecting the first direction and the second direction, from a surface of the sealing section which faces a surface on an opposite side of the circuit surface of the signal processing IC.

28. The current sensor according to claim 27, wherein a width of an edge of an extension portion, which is included in the extension portions, is narrower than a width of a part other than the edge of the extension portion.

29. The current sensor according to claim 27, wherein
an edge of an extension portion, which is included in the extension portions, includes a plurality of tooth portions aligned in a comb shape, and
a width of each of the plurality of tooth portions is from 0.5 times to twice a thickness of each of the first conductor portion, the second conductor portion, the fourth conductor portion, and the fifth conductor portion.

30. A current sensor module comprising:
the current sensor according to claim 27; and
a substrate in which the current sensor is arranged on a mounting surface, wherein
by an extension portion, which is included in the extension portions, being fixed to the mounting surface of the substrate, the sealing section is positioned above the mounting surface.

31. The current sensor module according to claim 30, wherein a width of an edge of the extension portion is narrower than a width of a part other than the edge of the extension portion.

32. The current sensor module according to claim 30, wherein
an edge of the extension portion includes a plurality of tooth portions aligned in a comb shape, and
a width of each of the plurality of tooth portions is from 0.5 times to twice a thickness of each of the first conductor portion, the second conductor portion, the fourth conductor portion, and the fifth conductor portion.

33. The current sensor module according to claim 30, wherein a distance between the mounting surface of the substrate, and a surface of the sealing section which faces the mounting surface, is 1 mm or more.
